(19) United States
(12) Patent Application Publication
(10) Pub. No.: US 2009/0214962 A1
(43) Pub. Date: Aug. 27, 2009

(54) EXPOSURE APPARATUS

(75) Inventor: Kazuhiko Mishima, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/368,921

(22) Filed: Feb. 10, 2009

(30) Foreign Application Priority Data
Feb. 19, 2008 (JP) 2008-037566

(51) Int. Cl. G03B 27/44; G03F 7/20

(52) U.S. Cl. 430/30; 355/46; 356/509

(57) ABSTRACT

An exposure apparatus includes a plurality modules and a controller, each module exposes a pattern of an original onto a substrate by using light from a light source, wherein each module includes a position detector configured to detect a position of the original or the substrate that has an alignment mark used for an alignment between the original and each shot on the substrate, wherein the controller has information relating to an alignment error of a detection result by the position detector which is set to each module, and wherein the exposure apparatus further includes a reducing unit configured to reduce a difference of the alignment error among modules.

### BACKGROUND OF THE INVENTION

1. Field of the Invention

The present invention relates to an exposure apparatus.

2. Description of the Related Art

An exposure apparatus configured to expose a pattern of an original, such as a mask and a reticle, onto a substrate is conventionally known. A throughput is an important parameter in the exposure. A highly precise alignment between the original and the substrate is critical.

For improved throughput, Japanese Patent Laid-Open No. (“JP”) 2007-294583 provides an exposure apparatus that includes a plurality of exposure units or modules, each of which includes an illumination apparatus, an original, a projection optical system, and a substrate, and commonly utilizes an original supply part.

In order to maintain the alignment accuracy, one known method obtains a correction value used to correct an alignment error by exposing and developing a test substrate (or a pilot wafer) and by inspecting the developed substrate, and sets the correction value in an exposure apparatus. The alignment error contains a tool induced shift (“TIS”), a wafer induced shift (“WIS”), and a TIS-WIS interaction. The TIS is an error caused by an apparatus (a position detector in an alignment optical system). The WIS is an error caused by a wafer process. The TIS-WIS Interaction is an error caused by the interaction between the TIS and the WIS. The correction value of the alignment error includes shot arrangement components such as a magnification, a rotation, an orthogonal degree, and a high order function, and shot shape components, such as a magnification, and a rotation, a skew, a distortion, and a high order function. JP 2007-158034 writes alignment information in a recipe that defines a substrate processing condition.

JP 2007-294583 premises that a plurality of modules exposes different original patterns onto a substrate (paragraph 0002 in JP 2007-294583), but a plurality of modules may expose the same original pattern onto one substrate. For example, each module exposes the same original pattern (first pattern), and then exposes another but the same original pattern (second pattern) onto another layer on the substrate. However, when a module that has exposed the first pattern is different from a module that has exposed the second pattern, the overlay accuracy may degrade for some substrate between the first pattern and the second pattern, because the alignment errors differ among these modules. This problem may be solved by making a substrate correspond to its processing module, but the management becomes complex. Therefore, in exposing one substrate with a plurality of modules, it is necessary to reduce alignment-error deviations among modules.

The alignment-error deviations among modules are caused by a position detector of an alignment optical system, stages configured to drive an original and a substrate, and interferometers configured to detect positions of the stages, etc. As described above, the TIS is inherent to the position detector of the alignment optical system. In addition, a shape difference of the bar mirror of the interferometer attached to the stage causes a position detection error, and finally an alignment error. Moreover, different flatness of a chuck configured to attach the original or the substrate to the corresponding stage causes a deformation of the substrate, positional shifts of an alignment mark and an overlay mark used for the overlay inspection, and finally an alignment error. In addition, a wavelength of a light source in the interferometer varies according to the environment, such as the atmospheric pressure, the temperature, and the humidity, and a measurement error occurs. The interferometer that controls a plurality of stages or a plurality of types of stages is significantly subject to such environmental influence.

### SUMMARY OF THE INVENTION

The present invention provides an exposure apparatus having high alignment accuracy.

An exposure apparatus according to one aspect of the present invention includes a plurality modules and a controller, each module exposes a pattern of an original onto a substrate by using light from a light source. Each module includes a position detector configured to detect a position of the original or the substrate that has an alignment mark used for an alignment between the original and each shot on the substrate. The controller has information relating to an alignment error of a detection result by the position detector which is set to each module. The exposure apparatus further includes a reducing unit configured to reduce a difference of the alignment error among modules.

An exposure apparatus according to another aspect of the present invention configured to expose a pattern of an original onto a substrate by utilizing light from a light source includes a plurality of movable stages each mounted with the original or substrate, a plurality of interferometers configured to detect positions of the plurality of stages, and a reducing unit configured to reduce an environmental deviation of a wavelength of the light used for each of the plurality of interferometers.

Further features of the present invention will become apparent from the following description of exemplary embodiments with reference to the attached drawings.

### BRIEF DESCRIPTION OF THE DRAWINGS

FIG. 1 is a block diagram of a multi-module type exposure apparatus according to a first embodiment of the present invention.

FIG. 2 is a plane view showing a shot arrangement on a wafer for the exposure apparatus shown in FIG. 1.

FIG. 3 is an enlarged plane view of an alignment mark used for an alignment of the exposure apparatus shown in FIG. 1.

FIG. 4 is an optical path showing a structure of an interferometer applicable to the multi-module type exposure apparatus shown in FIG. 1.

FIG. 5 is an optical path for explaining a baseline measurement in each module in the multi-module type exposure apparatus shown in FIG. 1.

FIGS. 6A-6C are a sectional view and plane views showing a structure of the reference mark shown in FIG. 5.

FIG. 7 is a graph showing a light quantity change obtained from a reference mark.

FIG. 8 is a block diagram for explaining a wafer transportation system shown in FIG. 1.

FIG. 9 is a block diagram for explaining a reticle transportation system shown in FIG. 1.

FIG. 10 is a plane view of a wafer shown in FIG. 1.

FIG. 11 is a flowchart for explaining a correction method of an alignment error of the multi-module type exposure apparatus shown in FIG. 1.

FIG. 12 is a block diagram of an overlay inspector.

FIG. 13 is a flowchart as a variation of the flowchart shown in FIG. 11.

FIG. 14 is a flowchart as another variation of the flowchart shown in FIG. 11.

FIG. 15 is a structural example of a recipe used for a control system shown in FIG. 1.

FIGS. 16A and 16B are plane views of a grating wafer shown in FIG. 8.

FIG. 17 is a flowchart for explaining a method for correcting a difference between modules by using the grating wafer shown in FIG. 15.

### DESCRIPTION OF THE EMBODIMENTS

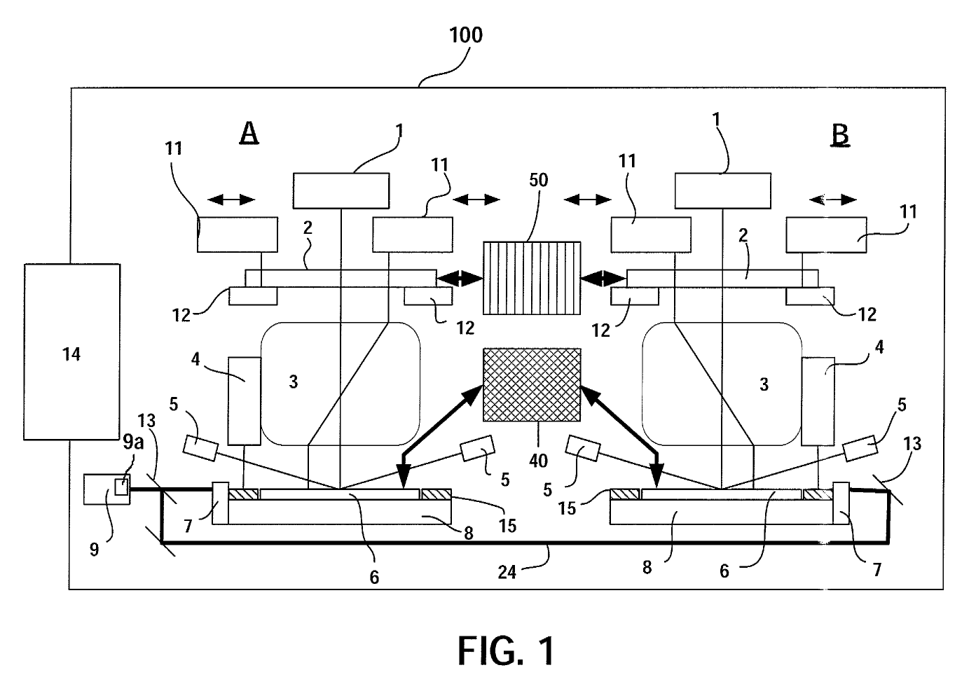

Referring now the accompanying drawings, a description will be given of an exposure apparatus according to one aspect of the present invention. The exposure apparatus 100 is, as shown in FIG. 1, a multi-module type exposure apparatus having a plurality of modules A and B. Each module exposes a pattern of an original onto a substrate by using light from a light source. In this embodiment, an A module and a B module have the same structure, and a prime is put on a corresponding reference numeral indicating a component of the B module. In the following description, unless otherwise specified, a reference numeral with no prime generalizes the reference numeral with the prime.

The exposure apparatus 100 may house a plurality of modules in one housing, each of which includes an illumination apparatus, an original, a projection optical system, a position detector, and a substrate, or each module may be housed in a separate housing. When a plurality of modules is accommodated in one housing, one control system can control the exposure environment and it is unnecessary to eject the substrate to the outside of the housing in moving the substrate between the modules.

Each module includes an illumination apparatus 1, a projection optical system 3, a wafer driving system, a focus system, a transportation system, an alignment system, and a control system 14, and exposes a pattern of a reticle 2 onto a wafer 6 by a step-and-scan manner. The present invention is also applicable to an exposure apparatus of a step-and-repeat manner.

The illumination apparatus 1 illuminates the reticle 2, and includes a light source and an illumination optical system. The light source can use a laser or a mercury lamp. The illumination optical system is an optical system configured to uniformly illuminate the reticle 2.

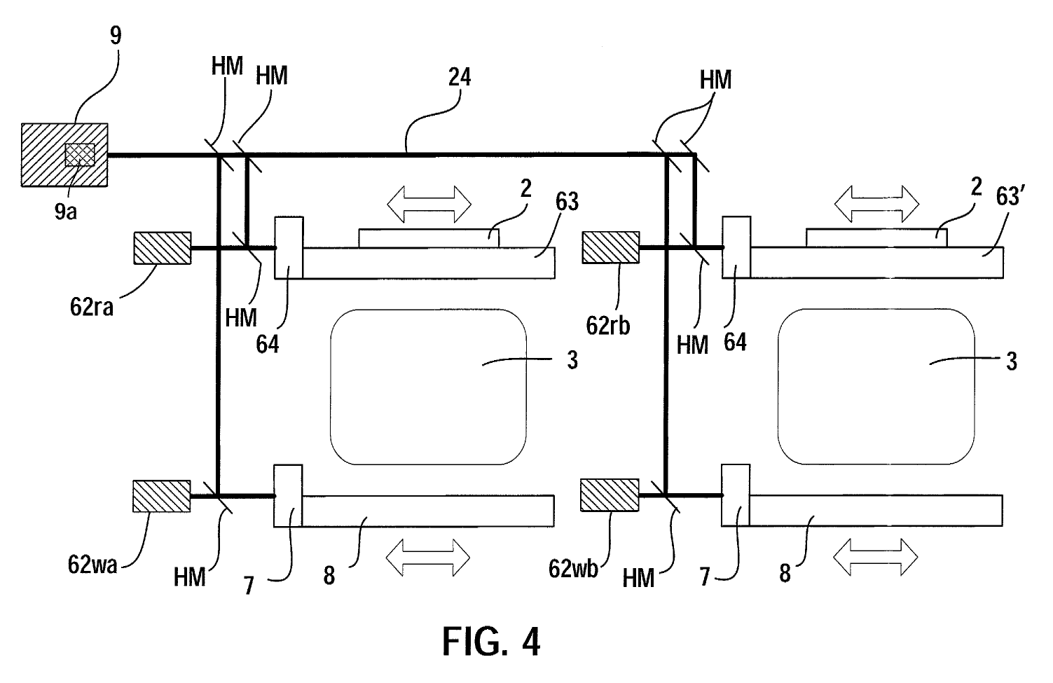

The reticle 2 has a circuit pattern or image, and is supported and driven by a reticle stage which is omitted in FIG. 1 and labeled as 63, 63′ in FIG. 4, which will be described later. A position of the reticle stage is always measured by the interferometer 9. The diffracted light emitted from the reticle 2 is projected onto the wafer 6 through the projection optical system 3. In order to expose the wafers 6, 6′ with the same pattern, the reticles 2, 2′ of this embodiment has the same pattern. The reticle 2 and the wafer 6 are optically conjugate with each other. Since each module in the exposure apparatus 100 serves as a scanner, the reticle pattern is transferred onto the wafer 6 by synchronously scanning the reticle 2 and the wafer at a speed ratio corresponding to a reduction magnification ratio.

The projection optical system 3 projects the light that reflects the reticle pattern onto the wafer 6. The projection optical system 3 may use a dioptric optical system, a catadioptric optical system, or a catoptric optical system. The immersion exposure may be realized by immersing in the liquid a final optical element of the projection optical system 3 which is closest to the wafer 6.

The wafer 6 is replaced with a liquid crystal substrate in another embodiment, and represents an object to be exposed. A photoresist is applied onto the surface of the wafer 6. The wafer 6 is exposed with a pattern, and an area for one exposure is referred to as a shot. The wafer 6 has an alignment mark 6b used for the alignment between the reticle 2 and each shot 6a, and the alignment mark 6b is measured by an off-axis (“OA”) scope 4.

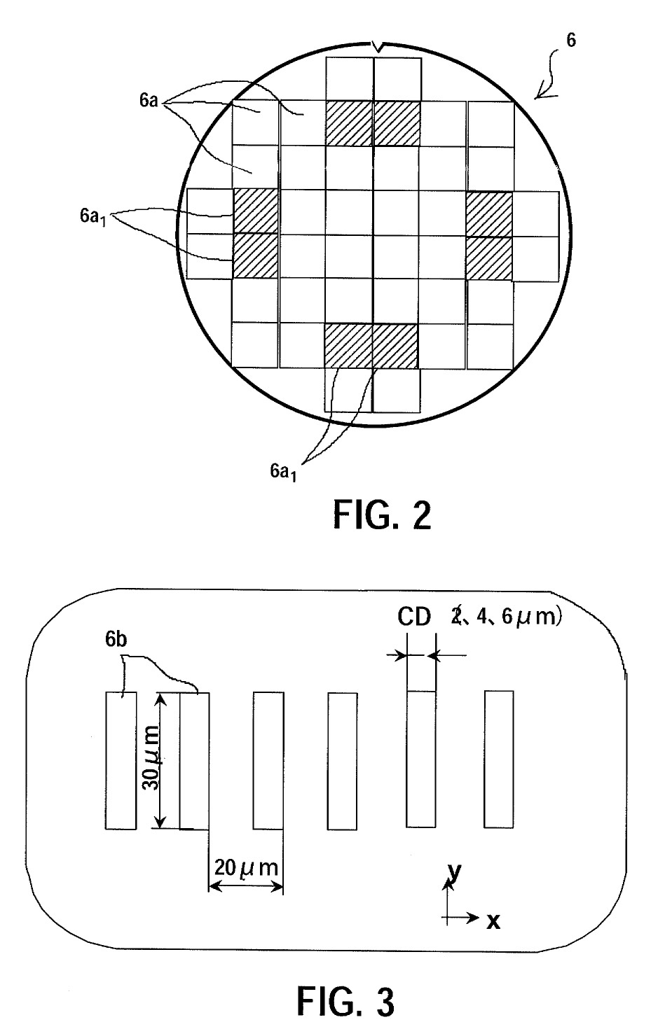

FIG. 2 is a plane view of the shots 6a arranged on the wafer 6 in a matrix shape. As shown in FIG. 2, the wafer 6 is divided into a plurality of rectangular shots 6a. This embodiment adopts a global alignment system that selects hatched shots 6a₁ among the shots 6a, and detects alignment marks corresponding only to the selected shots 6a₁ with an alignment system while driving the wafer with the wafer stage 8.

FIG. 3 is a plane view showing one example of the alignment marks 6b. The alignment marks 6b are previously formed on each shot 6a on the wafer 6. The alignment mark 6b shown in FIG. 3 has a single edge structure, and six rectangular marks having a size of 30 μm in the longitudinal direction are arranged at intervals of 20 μm. A size in the width direction (CD: critical dimension) of 2 μm, 4 μm, or 6 μm is used. In FIG. 3, they are arranged along the X direction, but marks that are rotated by 90° are also arranged in the Y direction. The alignment mark 6b may adopt a double edge structure in which one mark has an inner and outer double rectangular structure.

The alignment mark 6b is formed in a scribe line of each shot 6a to be exposed on the wafer 6, or between two adjacent shots 6a. The global alignment system detects all the alignment marks 6b corresponding to the selected shots 6a₁. Next follows a statistic process, such as a least squares approximation, and calculations of a positional shift of the wafer 6, a wafer magnification, an orthogonal degree, and a reduction magnification of the shot arrangement grating based on a detection result except for conspicuously deviate detection results from the overall tendency of the detection result.

The wafer driving system drives the wafer 6, and includes the wafer stage 8 and the interferometer 9. The wafer stage 8 utilizes a linear motor, is configured movable in each of the XYZ axes and their rotational directions, and supports and drives the wafer 6 via the chuck (not shown). A position of the wafer stage 8 is always measured by the interferometer 9 that refers to a bar mirror 7. A reference mark 15 is formed on the wafer stage 8. In exposing a reticle pattern onto the wafer 6, the wafer stage 8 and the reticle stage are driven based on a result calculated by the global alignment system.

In general, a wavelength of the interferometer changes due to environmental factors (including the air atmosphere, the temperature, the humidity, etc.) and a fluctuation of a light source of the interferometer, and a measurement value changes. In the multi-module type exposure apparatus, when the interferometer used for the wafer stage independently changes in each module, the alignment accuracy lowers. In addition, when the interferometer used for the reticle stage independently changes in each module, a positional relationship between the reticle and the wafer may destroy. Accordingly, the exposure apparatus 100 use a common light source for all the interferometers. More specifically, the light from a light source 9a used for the position detection which is installed in the interferometer 9 shown in FIG. 1 is used through mirrors 13 for the interferometer for the wafer stage 8 and the interferometer for the reticle stage in the A module and the B module. Instead of these mirrors 13, optical fibers may be used.

FIG. 4 is an optical path diagram showing a configuration of the interferometers applicable to the exposure apparatus 100. In FIG. 4, the light from the light source 9a in the interferometer 9 is led to the bar mirrors 7, 7′, 64, and 64′ in each interferometer by each half mirror HM in a deflection optical system. Reference numerals 64, 64′ denote bar mirrors for the interferometer used for the reticle stage 63. The light is reflected on the bar mirror, transmits the half mirror HM, and is detected by a corresponding one of detectors 62Wa, 62ra, 62wb, and 62rb of the interferometer 9, and thereby a position of each stage can be detected. In FIG. 4, all the interferometers have one common light source, but only the wafer stages 8, 8′ or only the reticle stages 63, 63′ may use a common light source.

Use of a common light source standardizes the influence of the wavelength change of the light source among modules or among stages (the wafer stages and the reticle stages), and can reduce scattering (differences) of the alignment error. When the light source is not commonly used, a common measurement apparatus (not shown) configured to measure the environmental factor may be provided, and a measurement result of the common measurement apparatus may be used to correct a control error of the interferometer in each module. Thus, use of the common light source or the common environment measurement apparatus can reduce differences among modules or among stages, and achieve a highly precise alignment. A relative position between the reticle 2 and the wafer 6 may be precisely controlled by using the above method so as to reduce a difference between the wafer stage and the reticle stage in the same module.

The focus system detects a position on the wafer surface in the optical-axis direction so as to position the wafer 6 at a focus position of an image formed by the projection optical system 3. The focus system includes a focus position detector 5. More specifically, the focus position detector 5 obliquely irradiates the light that has passed a slit pattern onto the wafer surface, photographs the slit pattern reflected on the wafer surface through an image sensor, such as a CCD, and measures a focus position of the wafer 6 based on the position of a slit image obtained by the image sensor.

The alignment system includes a Fine Reticle Alignment (“FRA”) system, a Through The Reticle (“TTR”) system, a Through The Lens (“TTL”) system, and an Off-Axis (“OA”) system.

The FRA system includes an alignment scope, and observes a reticle reference mark (not shown) formed on the reticle 2 and a reticle reference mark 12 formed on the reticle stage through an FRA scope (position detector) 11, for an alignment between them. These reticle reference marks are alignment marks, illuminated by the illumination apparatus 1, and simultaneously observed by the FRA scope 11. For example, the reticle reference mark (not shown) is formed as one first mark element on a surface of the reticle 2 on the side of the projection optical system 3, and a pair of second mark elements is provided on the reticle reference marks 12. The FRA scope 11 is used for their alignment so that the first mark element is arranged between the second mark elements.

The TTR system is a system configured to observe the reticle reference mark (not shown) formed on the reticle 2 and the stage reference mark 15 formed on the wafer stage 8 through the projection optical system 3 and the FRA scope 11 for their alignment. The reticle reference mark (not shown) is also referred to as a baseline (“BL”) mark or a calibration mark. The BL mark corresponds to the center of the reticle pattern. These reference marks are alignment marks, illuminated by the illumination apparatus 1, and simultaneously observed by the FRA scope 11. The FRA scope 11 is configured to move above the reticle 2, and observe both the reticle 2 and the wafer 6 via the reticle 2 and the projection optical system 3, and to also detect the positions of the reticle 2 and the wafer 6. The scope of the FRA system and the scope of the TTR system may be separately provided. For example, the BL mark (not shown) is formed as one third mark element on the reticle 2 on the side of the projection optical system 3, and one fourth mark element is formed on the stage reference mark 15. Next, the FRA scope 11 is used for their alignment so that the third mark element can overlap the fourth mark element.

The TTL system measures the stage reference mark 15 via the projection optical system 3 by using a scope (not shown) and the non-exposure light. For example, the non-exposure light of the He—Ne laser (with an oscillation wavelength of 633 nm) is led to the optical system via an optical fiber so as to Koehler-illuminate the stage reference mark 15 on the wafer 6 through the projection optical system 3. The reflected light from the stage reference mark 15 forms an image in the image sensor in the optical system from the projection optical system 3 in a direction opposite to the direction of the incident light. The image is photoelectrically converted by the image sensor, and the video signal undergoes a variety of image processes so as to detect the alignment mark.

The OA system detects the alignment mark of the wafer 6 by using the OA scope 4 without interposing the projection optical system 3. The optical axis of the OA scope 4 is parallel to the optical axis of the projection optical system 3. The OA scope 4 is a position detector that houses an index mark (not shown) arranged conjugated with the surface of the reference mark 15. It can calculate arrangement information of the shots formed on the wafer 6 based on the measurement result of the interferometer 9 and the alignment mark measurement result by the OA scope 4.

Prior to this calculation, it is necessary to obtain a baseline that is an interval between the measurement center of the OA scope 4 and the projected image center (exposure center) of the reticle pattern. The OA scope 4 detects a shift amount from the measurement center of the alignment mark 6b in the shot 6a on the wafer 6, and the center of the shot area is aligned with the exposure center when the wafer 6 is moved from the OA scope 4 by a distance made by this shift amount and the baseline. It is necessary to regularly measure the baseline since the baseline changes over time.

The shot shape information can be obtained by providing alignment marks at a plurality of points on the shot and by measuring them. More precise alignment and exposure is available by correcting the shot shape based on the shot shape information.

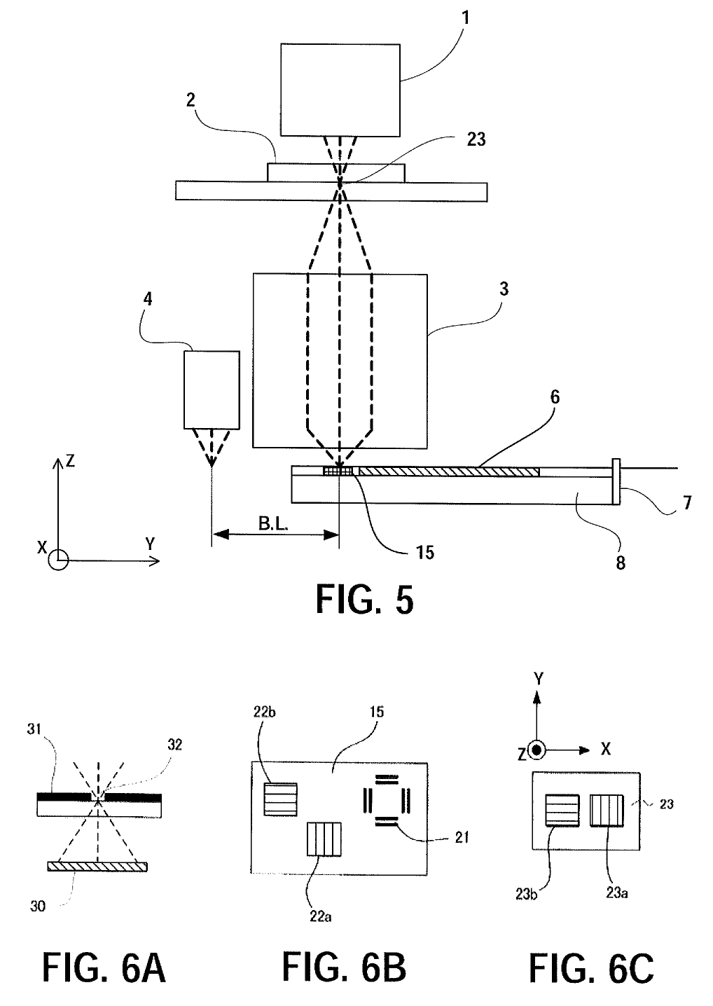

A measurement method of a baseline will now be described with reference to FIGS. 5 and 6C. FIG. 5 shows a BL mark 23 formed on the reticle 2. FIG. 6C is a plane view of the BL mark 23. The BL mark 23 has a mark element 23a used to measure the X direction and a mark element 23b used to measure the Y direction. The mark 23a is a repetitive pattern of an opening and a light shielding part in the longitudinal direction (the X direction), and the mark 23b is formed as a mark having an opening in a direction orthogonal to the mark 23a. The BL mark 23 of this embodiment uses the mark elements 23a and 23b along the XY directions, since the XY coordinate system is defined as shown in FIG. 6C, but an orientation of each mark element is not limited to this embodiment. For example, the BL mark 23 may have a measurement mark that inclines to the XY axes by 45° or 135°. When the mark elements 23a and 23b are illuminated by the illumination apparatus 1, the projection optical system 3 forms patterned images of the transmission part (opening) of the mark elements 23a and 23b on the best focus position on the wafer side.

Next, as shown in FIGS. 6A and 6B, the reference mark 15 includes a position measurement mark 21 which the OA scope 4 can detect, and mark elements 22a and 22b which are as large as the projected images of the mark elements 23a and 23b. FIG. 6A is a sectional view of the reference mark 15, and FIG. 6B is a plane view of the reference mark 15. The mark elements 22a and 22b include a light shielding member 31 having a light shielding characteristic to the exposure light, and a plurality of openings 32. FIG. 6A shows only one opening for convenience. The light that has transmitted the opening 32 reaches the photoelectric conversion element 30 formed under the reference mark 15. The photoelectric conversion element 30 can measure the intensity of the light that has transmitted the opening 32. The position measurement mark 21 is detected by the OA scope 4.

Next follows a description of a method for calculating the baseline by using the reference mark 15. Initially, the mark elements 23a and 23b are driven in place where the exposure light passes through the projection optical system 3. A description will now be given of the mark element 23a. This description is applicable to the mark element 23b. The moved mark element 23a is illuminated by the illumination apparatus 1. The projection optical system 3 forms an image as a mark pattern image the light that has passed the transmission part of the mark element 23a, at the imaging position on the wafer space. By driving the wafer stage 8, the mark element 22a having the same shape is arranged at a correspondence position of the mark pattern image. At this state, the reference mark 15 is arranged on the imaging surface (best focus surface) of the mark element 23a, and an output value of the photoelectric conversion element 30 is monitored while the mark element 22a is driven in the X direction.

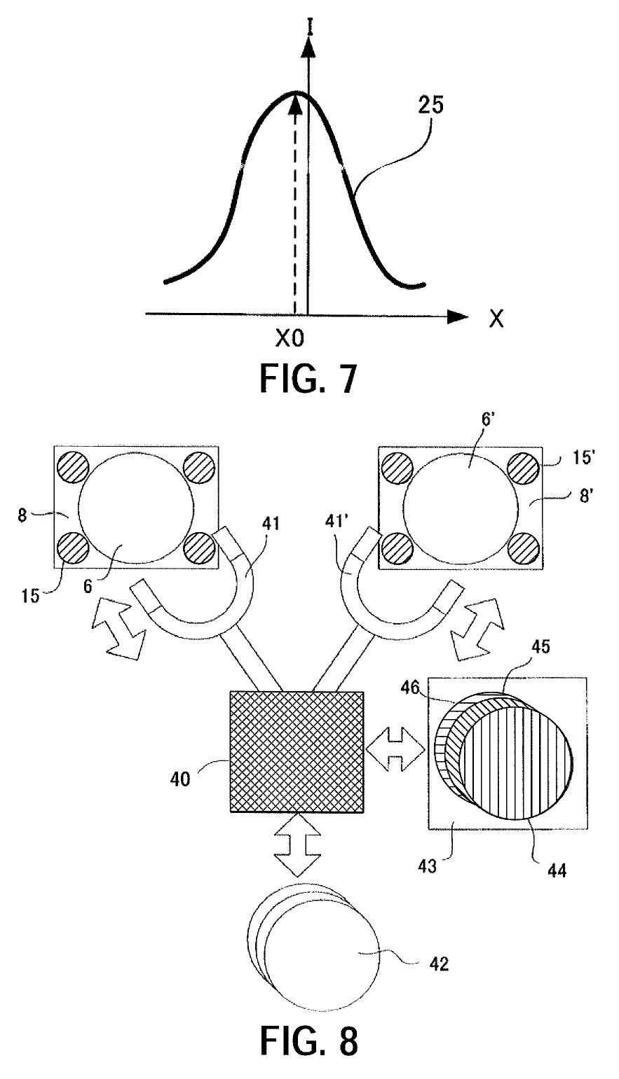

FIG. 7 is a graph that plots a position of the mark element 22a in the X direction and an output value of the photoelectric conversion element 30. In FIG. 7, an abscissa axis denotes the position of the mark element 22a in the X direction, and an ordinate axis denotes an output value I of the photoelectric conversion element 30. As relative positions between the mark element 23a and the mark element 22a are varied, the output value of the photoelectric conversion element 30 is varied. In this change curve 25, a position X0 gives a maximum intensity where the mark element 23a accords with the mark element 22a. A position of the projected image of the mark element 23a by the projection optical system 3 on the wafer space side can be calculated by calculating the position X0. The position X0 can be stably and accurately acquired when a peak position in the change curve 25 is calculated in a predetermined area through a gravity calculation, a function approximation, etc.

A position X1 of the wafer stage 8 is obtained from the interferometer 9, which provides overlapping between the mark elements 22a and 22b and the mark elements 23a and 23b in the Z direction. In addition, a position X2 of the wafer 8 is obtained from the interferometer 9, which provides overlapping between the index mark in the OA scope 4 and the position measurement mark 21 in the Z direction, Thereby, the baseline can be calculated by X1-X2.

While the above description assumes that the reference mark 15 of the projected image is located on the best focus surface, the reference mark 15 may not be located on the best focus surface in the actual exposure apparatus. In that case, the best focus surface is detected and the reference mark 15 can be arranged there by monitoring the output value of the photoelectric conversion element 30 while the reference mark 15 is driven in the Z direction (optical-axis direction). If it is assumed that the abscissa axis denotes a focus position and the ordinate axis denotes the output value I in FIG. 7, the best focus surface can be calculated by a similar process.

When the reference mark 15 shifts in the XY directions as well as in the Z direction, after predetermined precision is secured through a measurement in one direction, a position in another direction is detected. The best position can be finally calculated by alternately repeating the above flow. For example, while the reference mark 15 shifts in the Z direction, it is driven in the X direction for a rough measurement and an approximate position in the X direction. Thereafter, it is driven in the Z direction and the best focus surface is calculated. Next, the best position in the X direction can be calculated precisely by again driving it in the X direction on the best focus surface. Usually, a pair of alternate measurements can find a precise position. While the above example initially starts the measurement in the X direction, a precise measurement is available even when the measurement starts with the Z direction.

When the apparatus and the wafer 6 are not in the ideal states, the exposed wafer 6 has a slight alignment error. Usually, each component of the alignment error is analyzed, fed back to the exposure apparatus for calibration, and used for the exposure of the subsequent wafers 6. The alignment error components in the shot arrangement state include a shift component of all the shots, a primary component, such as a magnification, a rotation, and an orthogonal degree of each shot arrangement, and a high order component that occurs in an arc shape, and are calculated as X and Y individual components. The shot shape includes a wide variety of shape components, such as a shot's magnification and rotation, a rhomb shape, and a trapezoid shape. In particular, in the scanner, the shot's rhomb component is likely to occur. The shot arrangement component and the shot shape component are fed back to the exposure apparatus and corrected.

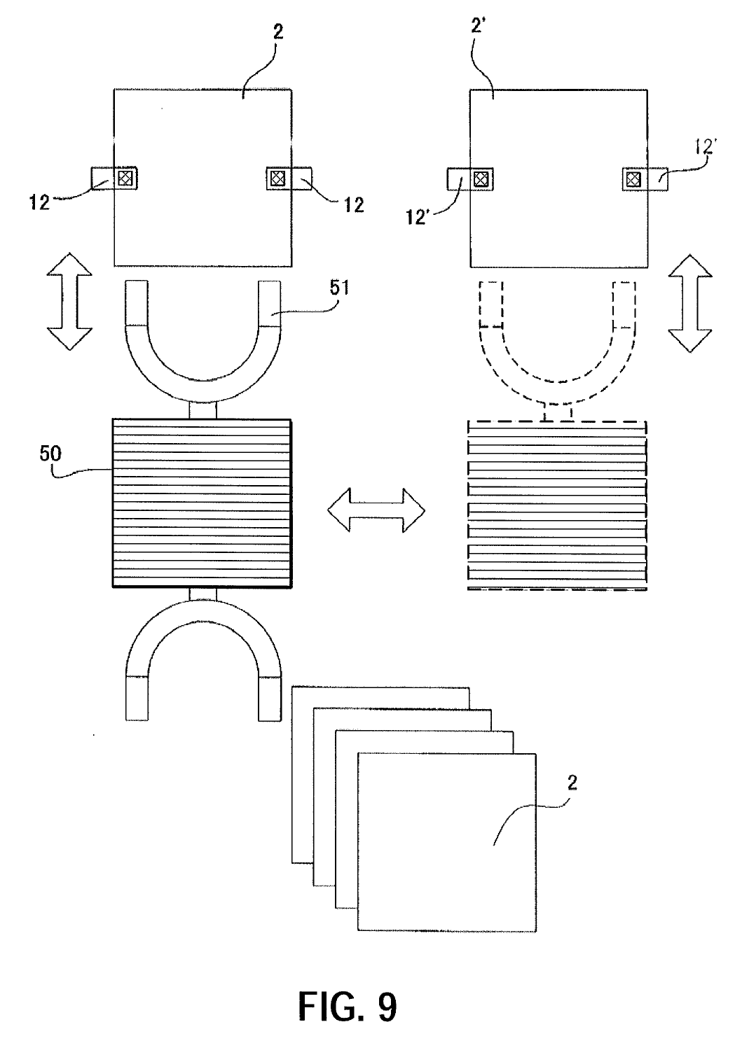

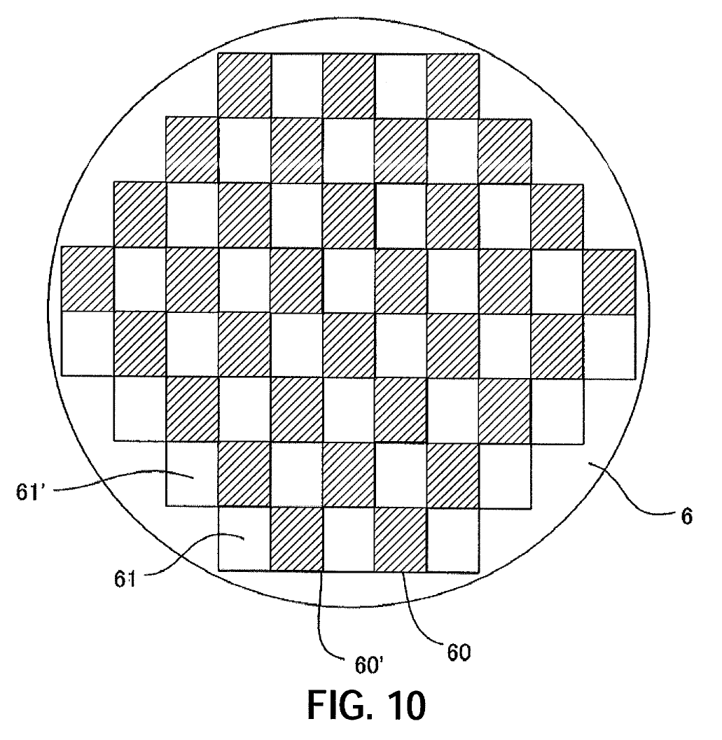

The transportation system includes one wafer transportation system 40 configured to transport the wafer 6 to the wafer stage 8, and one reticle transportation system 50 configured to transport the reticle to the reticle stage. FIG. 8 is a block diagram of the wafer transportation system 40. FIG. 9 is a block diagram of the reticle transportation system 50.

As shown in FIG. 8, initially, a plurality of wafers 42 that has not yet been exposed is supplied to the wafer transportation system 40 from a coater that applies the resist. The supplied wafer 42 is sequentially transported to the wafer stage 8 in each module by a wafer hand 41. The wafer 6 that has been exposed is collected by the wafer hand 41, and transported to a developer (not shown) that develops the resist. The wafer transportation system 40 can also transport the wafer between both modules. Moreover, the exposure apparatus 100 further includes a stocker 43 configured to house a stage-calibration wafer, and can import calibration wafers 44 to 46 to and export them from each module.

As shown in FIG. 9, the reticle 2 is appropriately transported to the reticle stage from a stocker that stores a plurality of reticles 2 in accordance with a command of the controller 14. At that time, the reticle 2 can be arranged on the reticle stage via a particle inspector (not shown) that inspects a particle on the reticle 2. In FIG. 9, one reticle transportation system 50 can move between both modules, and the reticle 2 is mounted on respective modules sequentially but the number of the reticle transportation systems 50 is not limited. This embodiment prepares for the number of reticles 2 having the same pattern corresponding to the number of modules. After the exposure ends, the reticle 2 is collected from the reticle stage in each module by the reticle transportation system 50 in the reverse procedure.

The controller 14 integrally controls the alignment measurement operation and the exposure operation of a plurality of modules in the exposure apparatus 100 by one recipe that defines the process condition of the wafer 6. The recipe contains correction values (offsets) used to correct the alignment errors for each module. In addition, the correction value that corrects the alignment error can be set for each stage. The controller 14 includes the recipe, which will be described later, and a memory (not shown) configured to store information necessary for other controls. Hence, the controller 14 uses the measurement result of the OA scope 4 and the correction value used to correct the alignment error set for each module, and controls the exposures of the A and B modules by correcting the alignment errors of the reticle 2 for each module.

The alignment error is caused by the WIS, the TIS, and the TIS-WIS Interaction.

The WIS is caused by dishing and erosion, in which chemical mechanical polishing (“CMP”) that provides the wafer planarization that destroys the alignment mark, and uneven coating of the resist onto the surface of the substrate before exposure. However, when the CMP condition and the resist coater state are stable, the alignment error can be corrected by reducing differences among a plurality of wafers, although the dishing and the uneven coating occur.

Since TIS is caused by an aberration (in particular coma and spherical aberration) of the position detector, such as the OA scope 4, and a manufacture error, such as an optical telecentricity error, it cannot be actually perfectly eliminated. In other words, the position detector has more or less a residue TIS component.

The WIS is a uniformly correctable component once a type of wafer to be exposed, such as a CMP condition and a resist application condition, is determined, and the TIS is also correctable once the apparatus is fixed unless there is a change over time. However, the TIS-WIS Interaction occurs due to an interaction between WIS and TIS and cannot be removed simply by correcting the WIS and TIS.

When a plurality of wafers having a common WIS are detected by a plurality of position detectors having different TISs and exposed in a certain process, alignment errors caused by a TIS-WIS Interaction will differ. Therefore, a multi-module type exposure apparatus having a plurality of position detectors has a problem in that a highly precise alignment cannot be obtained in the uniform feedback of alignment errors using the a pilot wafer.

In addition, an alignment precision may lower due to a difference of a bar mirror's shape for the interferometer among stages and its change over time. Moreover, as a result of that the flatness differs among wafers (deformations of wafers) due to a wafer chuck's shape, a shot's position shifts and each stage has different alignment precision. In general, a position of an alignment mark on a wafer is different from a position of a mark for the overlay inspection, and positional shifts of these marks differ due to the wafer deformation.

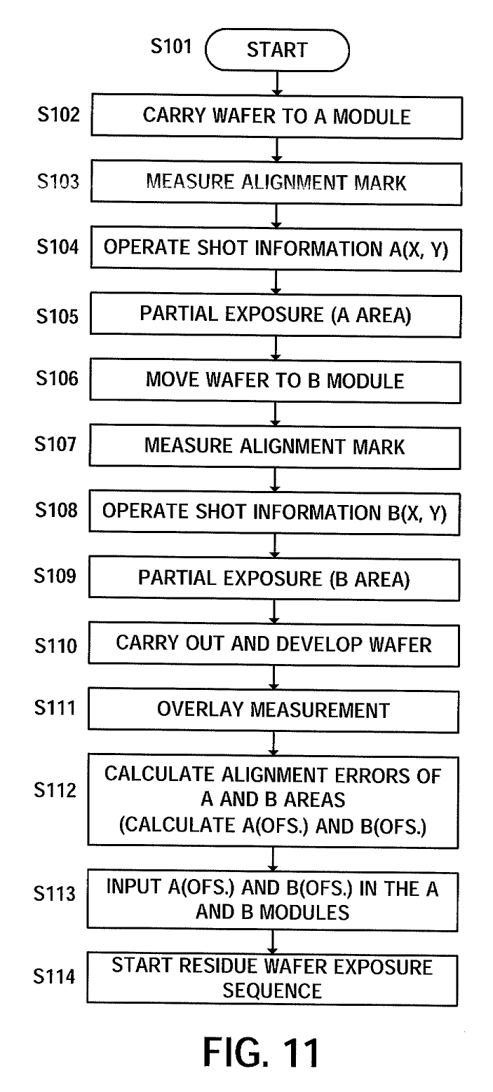

Referring now to FIGS. 10 to 12, a description will be given of a correction method of an alignment error (or a setting method of a correction value). Here, FIG. 10 is a plane view of the wafer 6. FIG. 11 is a flowchart for explaining the correction method of the alignment error in the exposure apparatus 100.

In response to an exposure command (S101), at least one wafer 6 among a plurality of wafers 6 is carried in the A module by the wafer transportation system 40 (S102). Next, the OA scope 4 of the A module measures a plurality of alignment marks 6b formed on the carried wafer 6 (S103). The controller 14 calculates arrangement information A(X, Y) of the shot based on the information of the measured alignment marks 6b (S104). When a plurality of marks is formed in the shot 6a, the shot shape is also calculated. Next, the controller 14 exposes with the calculated shot arrangement information (S105). Here, shots to be exposed are those in a bevel area 60 (60′) in FIG. 10, which will be referred to as an “A area” hereinafter. When the exposure of the A area completed, the wafer 6 is collected from the A module by the wafer transportation system 40, and moved to the B module (S106).

The alignment marks on the wafer 6 that has been moved to the B module are measured (S107), and the shot arrangement information B(X, Y) is calculated (S108). Shots 6a₁ for which the alignment marks 6b are measured are the same shots between both modules. Ideally, the shot arrangement information B(X, Y) is identical to the shot arrangement information A(X, Y), but the values are different due to influences of the TIS and the TIS-WIS Interaction. A white area 61 (61′) in FIG. 10, which will be referred to as a “B area” hereinafter, is exposed based on the shot arrangement information B(X, Y) (S109).

This embodiment arranges the A area and the B area like a dice or checked pattern as shown in FIG. 10. In this arrangement, the A area and the B area are alternately and uniformly located on the wafer 6 (substrate surface). Hence, in calculating a correction value to cancel an alignment error, which will be described later, for example, the influence of the error component depending upon the position in the wafer 6 in the exposure area can be reduced. Conceivably, the error component depending upon the position in the wafer 6 surface is, for example, the precision of the surface shape of the bar mirror 7 in the interferometer 9 used to measure the position of the wafer stage 8. If the wafer 6 is halved into the A area and the B area, a position of the wafer stage 8 in the measurement of the alignment marks on the A area is distant from a position of the wafer stage 8 in the measurement of the alignment mark on the B area, and thus a position of the bar mirror 7 onto which a ray from the interferometer 9 is irradiated is distant. Therefore, the measurement error of the wafer stage position caused by the surface shape of the bar mirror 7 may be added to the alignment error. The dice or checked pattern can uniformly arrange the A area and the B area on the wafer surface, and can reduce this influence. The arrangement of the A area and the B area is not limited to the dice pattern arrangement shown in FIG. 10, and may use various arrangements.

When the entire B area is exposed, the wafer 6 is carried out of the exposure apparatus by the wafer transportation system 40 and developed (S110), and the overlay inspector is used for the overlay inspection of the development result (S111). The overlay inspector calculates a correction value or an offset value used to cancel the alignment error of each of the A and B areas. Assume that A(OFS.) denotes a correction value for the A area and B(OFS.) denotes a correction value for the B area (S112). These values are fed back to each module and stored in the recipe. Subsequently, the alignment is corrected based on the correction values for the exposure with the same recipe.

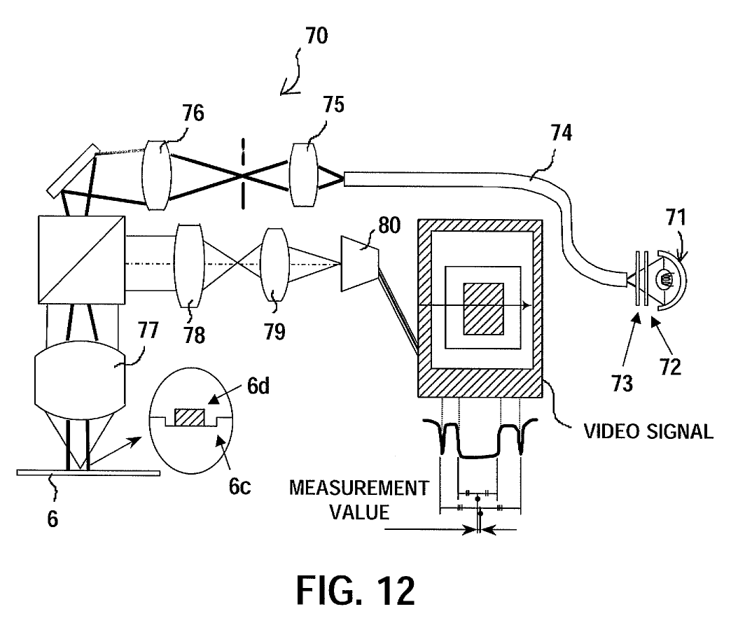

FIG. 12 is a block diagram of the overlay inspector 70. The overlay inspector 70 is an apparatus configured to measure the alignment and the distortion of the exposure apparatus, and to measure, as shown in FIG. 12, relative positions of two separately formed, overlay marks 6c and 6d. The overlay inspector 70 uses a halogen lamp for the light source 71, and selects a desired wavelength band through optical filters 72 and 73. Next, the illumination light is led to optical systems 75 to 77 by an optical fiber 74 so as to Kohler-illuminate the overlay marks 6c and 6d on the wafer 6. The light reflected on the wafer 6 is led to an image sensor 80, such as a CCD camera, by optical systems 77 to 79, and forms an image. When a variety of image processes are performed for a video signal generated by photoelectrically converting the image, the relative positions of the two overlay marks 6c and 6d are detected.

The residue wafers are exposed after the alignment errors are fed back. Since the correction value used to cancel the alignment error is fed back, the subsequent wafers are given precise alignment (S114). A(OFS.) and B(OFS.) are different because of the influence of the TIS-WIS interaction and a drawing error of the reticle that is used.

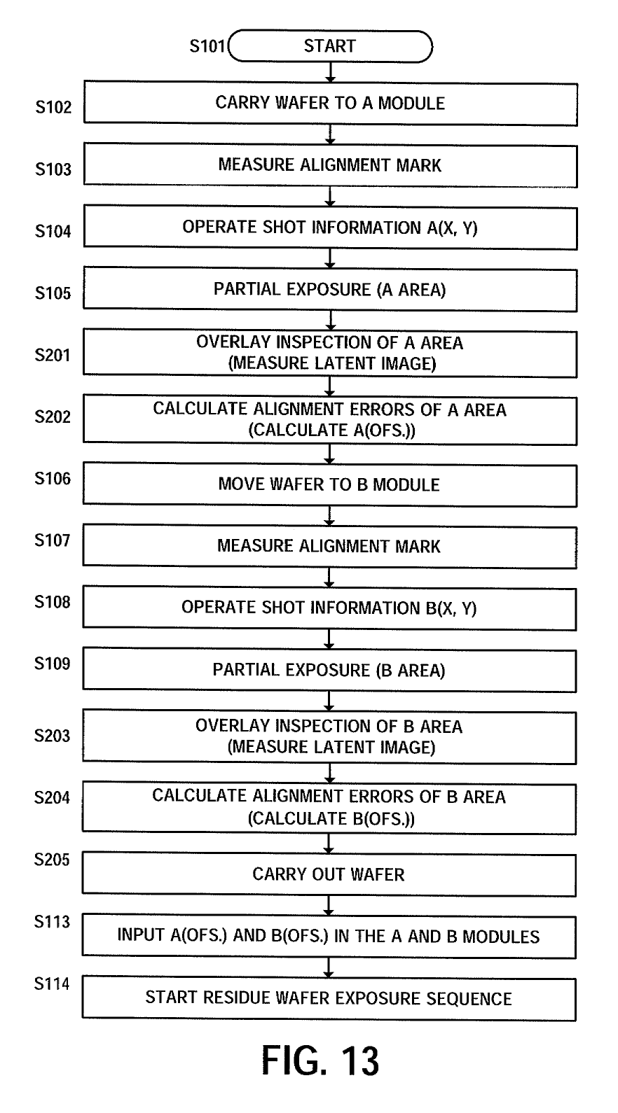

Referring now to FIG. 13, a description will be given of a correction method of the alignment error that does not use a developer or an overlay inspector. Those steps (S) in FIG. 13, which are the same as corresponding steps in FIG. 11, will be designated by the same reference numerals, and a description thereof will be omitted. FIG. 13 is different from FIG. 11 in that FIG. 13 has S201 to S205 instead of S110 to S112.

Similar to FIG. 11, after the A area is exposed (S101 to S105) and undergoes the overlay inspection (latent image measurement) with the OA scope 4 while mounted on the stage (S201). Since the refractive index of the exposed resist usually changes, the image can be observed by the OA scope 4. The OA scope 4 installs an algorithm configured to measure an alignment mark on the wafer 6 and an overlay mark for the overlay inspection. A correction value A(OFS.) of the alignment error of the A area detected by the OA scope 4 is calculated (S202). Thereafter, the wafer 6 is carried in the B module, and the B area is exposed (S106 to S109). Thereafter, the overlay inspection (latent image measurement) similarly follows with the OA scope 4′ (S203), and a correction value B(OFS.) of the alignment error of the B area detected by the OA scope 4 is calculated (S204). Thereafter, the wafer 6 is carried out of the exposure apparatus by the wafer transportation system 40 (S205), and the correction values A(OFS.) and B(OFS.) are fed back to the corresponding modules (S113). The correction value is stored in the recipe, and the alignment error is corrected based on the correction value for the exposure with the same recipe. Since the residue wafers are exposed while the correction value is fed back, a highly precise alignment of the wafer is available.

It is not always necessary to perform the overlay inspection of the A module with the OA scope 4 of the A module. In other words, after the A module terminates the exposure (S105), the B module may performs a flow down to the exposure without performing S201 and S202 (S106 to S109), and then the overlay inspections of both A and B areas may be performed with the OA scope 4′ of the B module. This configuration unifies the influence of TIS in the overlay inspections, and reduces an error.

The above method premises the overlay inspection, because the shift component and the rotation component (except for the orthogonal degree) among the shot arrangement information cannot be calculated once the wafer 6 is detached from the wafer stage 8. In other words, the correction value of the alignment error between modules can be calculated without an exposure or an overlay inspection when the influence of the shift component and the rotation component can be ignored.

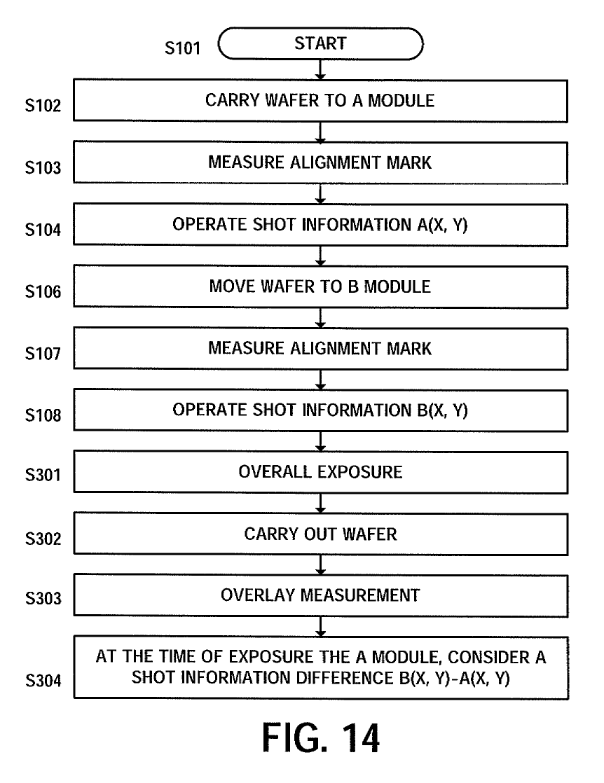

This method will now be described with reference to FIG. 14. Those steps in FIG. 14, which are the corresponding steps in FIG. 11, will be designated by the same reference numerals, and a description thereof will be omitted. FIG. 14 is different from FIG. 11 in that FIG. 14 has S301 to S304 instead of S105, S109 to S114.

The flow is similar down to the shot information operation A(X, Y) (S101 to S104). Next the wafer 6 is carried in the B module without an exposure (S106). The flow similar to the above is performed down to the shot information operation B(X, Y) (S107 to S108), and the entire wafer 6 is exposed based on B(X, Y) (S301). FIG. 14 does not have the partial exposure (S105, S109) shown in FIG. 11. When the exposure to the entire surface on the wafer 6 ends, the wafer 6 is carried out of the exposure apparatus and developed if necessary (S302), and the overlay inspection of the exposure result or the development result follows with the overlay inspector (S303). The overlay inspector calculates a correction value or an offset amount used to cancel an alignment error of the B module for the entire wafer 6. The correction value is fed back to the exposure apparatus 100. The subsequent wafers are exposed with calculated values of A(X, Y) and B(X, Y) (S304). In other words, the A module (second module) provides highly precise exposure with the correction value of the alignment error and {B(X, Y)−A(X, Y)}. The B module (first module) may weigh only the correction value of the alignment error. In the above plurality of methods, a baseline measurement is necessary prior to the measurement.

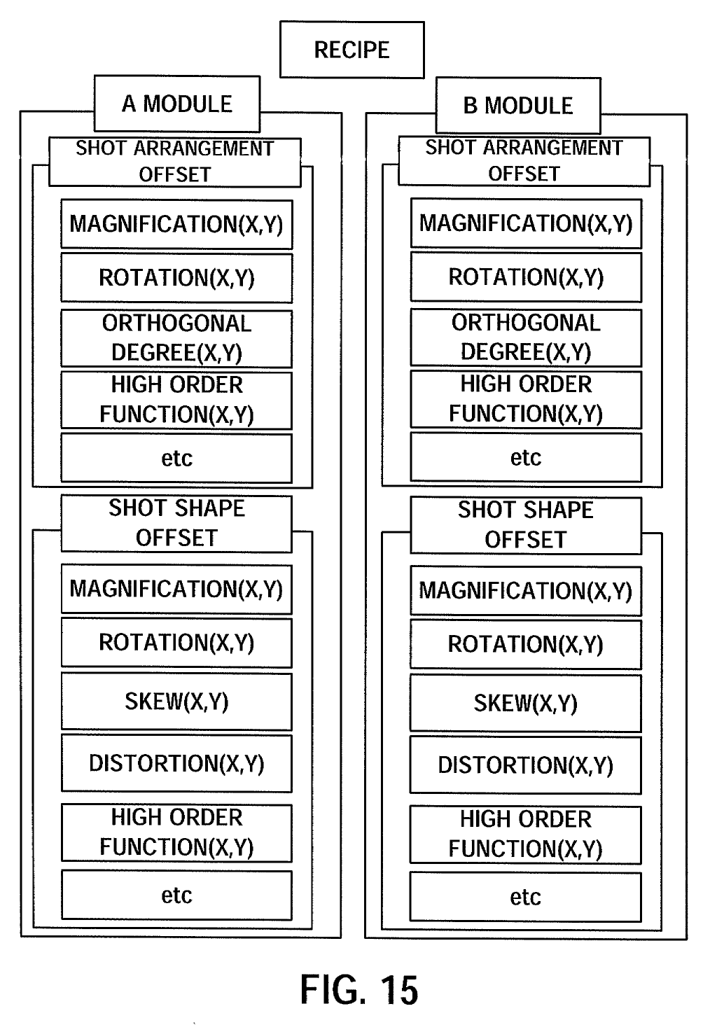

Referring now to FIG. 15, a description will be given of the correction value (offset) of the alignment error. As described above, the correction value includes the shift component of the entire shots, a primary component such as the magnification, the rotation and the orthogonal degree of each shot arrangement, and a high order component that occurs in an arc shape, and these are calculated as X and Y individual components. The shot shape contains a variety of shot components, such as a magnification, a rotation, a rhomb shape, and a trapezoid shape. Each component can be input, stored, and managed. The correction value is stored in the recipe. FIG. 15 shows an illustrative recipe configuration. A correction value can be input, stored, and managed for each of the A module and the B module. Since locations of the alignment mark and the overlay mark generally differ according to processes (recipes) of the wafer, a highly precise alignment can be achieved by providing the correction value to the recipe.

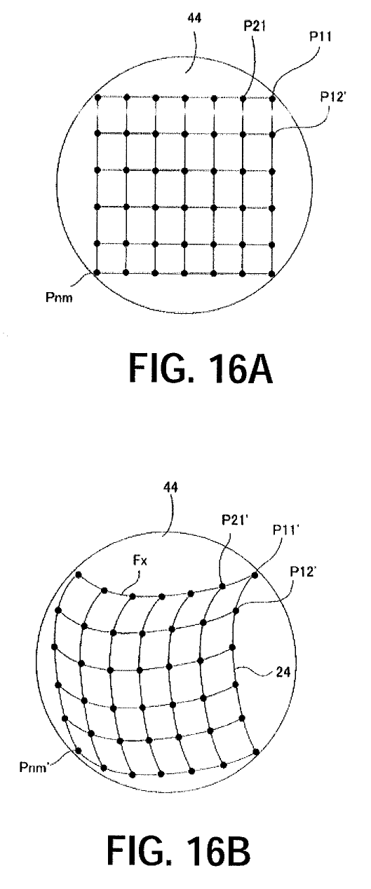

The previous embodiment calculates and corrects the correction value of the alignment error between modules by using the wafer 6 to be actually exposed. On the other hand, another embodiment measures and corrects differences between the stages. Referring now to FIGS. 8 and 16, a description will be given of this embodiment.

A wafer stocker 43 shown in FIG. 8 stores reference wafers used to recognize a grating state of the wafer stage 8. The reference wafer includes a grating wafer 44 used to recognize the grating state of the wafer stage, a focus wafer 45 used to recognize the focus precision of the wafer stage 8, and an adjustment wafer 46 used to recognize the adjustment state of the OA scope 4.

FIG. 16A is a plane view showing an arrangement of the alignment marks P11 to Pnm on the grating wafer 44. Marks P11 to Pnm are formed which can be detected by the OA scope 4 or the FRA scope 11 at black-dot positions of the ideal grating. The OA scope 4 sequentially measures the alignment marks formed at the black-dot points. The wafer stage having the ideal grating state is measured as a shape shown in FIG. 16A. However, when it shifts in the Y direction while it is driven in the X direction, or when it shifts in the X direction while it is driven in the Y direction, a measurement result shown in FIG. 16B is obtained. Conceivably, this is because the bar mirror 7 on the wafer stage 8 is not linearly shaped. A correction based on the information shown in FIG. 16B can provide position measurements and exposure while the wafer stage is returned to an ideal grating state. When the OA scope 4 and the FRA scope 11 are used for the measurements, both the bar mirror's shape with the OA scope 4 and the bar mirror's shape through the projection optical system can be obtained. A correction table may be stored as a function of Fx and Fy based on the measurement result shown in FIG. 16B, or a correction value at each grating point is stored and the in-between among the grating points may be linearly polarized. In either case, the grating information of the wafer stage can be calculated and corrected by using the grating wafer as a reference.

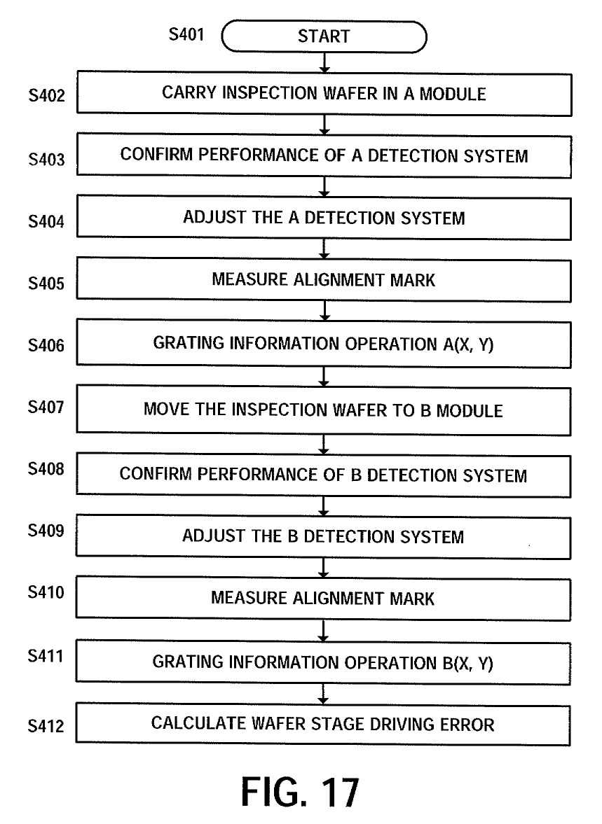

Referring now to FIG. 17, a description will be given of a method of correcting a difference between the actual modules by using a grating wafer 44. Initially, an inspection start command is issued (S401). A user may input the inspection start, or an apparatus may automatically start the inspection. In the latter, the automatic measurement may start when the controller 14 determines that a difference between A(X, Y) and B(X, Y) is greater than a threshold by using the method described in the first embodiment. When the inspection starts, the grating wafer 44 stored in the wafer stocker 43 is carried in the A module (S402). The grating wafer 44 may be carried in the A module from a unit other than the wafer stocker 43. The OA scope 4 measures the alignment mark on the grating wafer 44 mounted on the wafer stage 8 (S405).

The grating wafer 44 in this sequence also serves to recognize the adjustment state of the OA scope 4. Therefore, the performance of the OA scope 4 is recognized from the measurement result (S403), and if necessary, the OA scope 4 is adjusted (S404). The adjustment is performed with respect to the TIS component, such as the aberration of the OA scope 4 and the telecentricity. The OA scope 4 has a mechanism that can adjust the TIS component, and the adjustment method is not particularly limited. However, the adjustment wafer 46 may be used unless the grating wafer 44 serves to recognize the adjustment state of the OA scope 4.

After the adjustment to the OA scope 4 is completed, a plurality of alignment marks formed on the grating wafer 44 is measured (S405). A grating state A(X, Y) of the wafer stage 8 is calculated based on this measurement (S406). After the inspection ends, the wafer 44 is transported to the B module (S407), and similar adjustment and measurement are performed in the B module (S408 to S411). When the adjustment and measurement end, the wafer is carried out and the obtained grating information A(X, Y) and B(X, Y) are stored in the exposure apparatus. Next follows a calculation of the driving error of the wafer stage 8 (S412). Subsequently, the position measurement and exposure are performed based on this correction value of the driving error. Therefore, differences of the grating state among modules reduce and the ideal grating state can be guaranteed.

While the above grating wafer 44 premises the ideal grating state, an actual slight error is correctable. For example, the error component of the wafer itself can be cancelled by measuring the wafer at three states of 0°, 90°, and 180° in the measurement of S405. Thus, the sequence that includes measurements at some rotated positions can provide a highly precise correction.

The adjustment wafer 46 has a mark having a step corresponding to ⅛ times as large as the wavelength of the OA scope 4, and an adjustment state of the OA scope can be determined by utilizing the symmetry of a measurement signal.

The focus wafer 45 has highly precise flatness on both front and back surfaces of the wafer. When the focus wafer 45 is mounted on the wafer stage and measured by the focus system while it is driven in the XY directions, the focus error of the wafer stage 8 can be calculated.

In operation, each module may expose the same reticle pattern (first pattern) onto the wafer 6, and then expose another but the same reticle pattern (second pattern) on a different layer in the wafer 6. Even when a module that has exposed the first pattern is different from a module that has exposed the second pattern, the overlay accuracy of the wafer 6 is maintained between the first pattern and the second pattern, because an adjustment has been performed so that an alignment error among modules can be approximately equal.

This embodiment is applicable to an immersion exposure apparatus. In the immersion exposure apparatus, a dummy wafer is required to maintain the liquid at the non-exposure time, and the dummy wafer can be housed in the wafer stocker 43.

Next follows a manufacturing method of a device, such as a semiconductor integrated circuit device and a liquid crystal display device, according to one embodiment of the present invention. Here, a manufacturing method of a semiconductor device will be described in an example.

A semiconductor device is manufactured by a pretreatment process of making an integrated circuit on a wafer, and a post-treatment process of completing as a product the integrated circuit chip produced on the wafer by the pretreatment process. The pretreatment process includes the steps of exposing a substrate, such as a wafer and a glass plate, on which a photosensitive agent is applied by using the above exposure apparatus, and developing the substrate. The post-treatment process includes an assembly step (dicing and bonding), and a packaging step (sealing).

The device manufacturing method of this embodiment can manufacture a higher-quality device than ever.

This embodiment sequentially mounts a substrate to be actually exposed on a plurality of stages in the multi-module type exposure apparatus, detects its position with an alignment system, and uses obtained position detection information for each stage to correct differences among the stages and among the position detectors of the alignment system. In addition, at least one substrate is position-detected by a plurality of position detectors, exposed, and overlay-measured, and the measurement result is fed back to each stage for a highly precise alignment. Moreover, in order to obtain differences among stages, a reference wafer used for an adjustment is provided in the exposure apparatus so as to recognize a state of the exposure apparatus, to provide proper measurements and corrections, and to maintain a state in which the differences among the apparatuses are reduced. In addition, the measurement of the interferometer with the light emitted from one light source unifies the error generated from the environmental factor.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. For example, while this embodiment feeds back the alignment error of the OA scope 4, the alignment error of the FRA scope 11 may be fed back.

This application claims the benefit of Japanese Patent Application No. 2008-037566, filed Feb. 19, 2008, which is hereby incorporated by reference herein in its entirety.

What is claimed is:

1. An exposure apparatus comprising:
a plurality modules that each include a position detector;
a controller; and
a reducing unit,
wherein each module exposes a pattern of an original onto a substrate by using light from a light source,
wherein the position detectors are configured to detect a position of the original or the substrate that has an alignment mark used for an alignment between the original and each shot on the substrate,
wherein the controller has information relating to an alignment error of a detection result by the position detector which is set to each module, and
wherein the reducing unit is configured to reduce a difference of the alignment error among modules.

2. The exposure apparatus according to claim 1, wherein the unit sets a correction value used to correct the alignment error for each module.

3. The exposure apparatus according to claim 2, wherein the correction value is set for each stage configured to drive the original or substrate in each module.

4. The exposure apparatus according to claim 1, wherein each module further includes a projection optical system configured to project an image of the pattern of the original, and
wherein the alignment error is obtained as a result of that different areas on one substrate are exposed by the plurality of modules based on the detection result of the alignment mark on the substrate by the position detector in each module, and developed, and a development result is measured by an overlay inspector.

5. The exposure apparatus according to claim 1, wherein each module further includes a projection optical system configured to project an image of the pattern of the original, and
wherein the alignment error is obtained as a result of that different areas on one substrate are exposed by the plurality of modules based on the detection result of the alignment mark on the substrate by the position detector in each module, and the position detector in each module measures a latent image on a corresponding area.

6. The exposure apparatus according to claim 1, wherein each module further includes a projection optical system configured to project an image of the pattern of the original, and
wherein the alignment error is obtained as a result of that different areas on one substrate are exposed by the plurality of modules based on the detection result of the alignment mark on the substrate by the position detector in each module, and one of position detectors in the plurality of modules measures a latent image on a corresponding area.

7. The exposure apparatus according to claim 4, wherein the different areas on one substrate exposed by the plurality of modules are arranged like a dice pattern.

8. The exposure apparatus according to claim 2, wherein each module further includes a projection optical system configured to project an image of the pattern of the original,
wherein the position detector in each module detects the same alignment mark on the substrate, the substrate is exposed by a first module, and an overlay inspector measures an exposure result, and
wherein a correction value of an alignment error of the first module is obtained from a measurement result by the overlay inspector, and an alignment error of a second module different from the first module is an amount set based on a difference of a detection result between a position detector of the first module and a position detector of the second module, before the alignment error of the first module is corrected.

9. The exposure apparatus according to claim 1, wherein the position detector includes an alignment scope configured to observe the alignment mark, and the reducing unit adjusts a state of the alignment scope.

10. An exposure apparatus configured to expose a pattern of an original onto a substrate by utilizing light from a light source, the exposure apparatus comprising:
a plurality of movable stages each mounted with the original or substrate;
a plurality of interferometers configured to detect positions of the plurality of stages; and
a reducing unit configured to reduce an environmental deviation of a wavelength of the light used for each of the plurality of interferometers.

11. The exposure apparatus according to claim 10, wherein the unit commonly uses a light source for a position detection among the plurality of interferometers.

12. The exposure apparatus according to claim 11, further comprising a plurality of modules, each of which is configured to expose the pattern of the original onto the substrate by using the light from the light source, and includes at least one of the plurality of stages and at least one of the plurality of interferometers.

13. A device manufacturing method utilized in an exposure apparatus that includes a plurality modules that each include a position detector; a controller; and a reducing unit, wherein each module exposes a pattern of an original onto a substrate by using light from a light source, wherein the position detectors are configured to detect a position of the original or the substrate that has an alignment mark used for an alignment between the original and each shot on the substrate, wherein the controller has information relating to an alignment error of a detection result by the position detector which is set to each module, and wherein the reducing unit is configured to reduce a difference of the alignment error among modules, the method comprising:
exposing a substrate utilizing the exposure apparatus; and
developing the substrate that has been exposed.
